(19) United States
(12) Patent Application Publication
(10) Pub. No.: US 2020/0184246 A1
(43) Pub. Date: Jun. 11, 2020

(54) OPTICAL FINGERPRINT SENSING MODULE

(71) Applicant: Egis Technology Inc., Taipei (TW)

(72) Inventor: Chen-Chih FAN, Taipei (TW)

(21) Appl. No.: 16/661,237

(22) Filed: Oct. 23, 2019

Related U.S. Application Data
(60) Provisional application No. 62/775,485, filed on Dec. 5, 2018.

(30) Foreign Application Priority Data
Sep. 26, 2019 (CN) 201921620824.3

(51) Int. Cl. G06K 9/20; G06K 9/00

(52) U.S. Cl. CPC G06K 9/209; H01L 27/323; G06K 9/00006

(57) ABSTRACT

An optical fingerprint sensing module is provided, including a substrate, an image sensor disposed on the substrate, a frame disposed on the substrate, a lens, and a plurality of micro-lenses. The micro-lenses have an infrared cut-off material and are disposed above the image sensor. Light emitted from a display panel module is reflected by a finger and then sequentially propagates through the lens and the micro-lenses to reach the image sensor.

### CROSS REFERENCE TO RELATED APPLICATIONS

This application claims the benefit of U.S. Provisional Application No. 62/775,485, filed on Dec. 5, 2018, and claims priority of China Patent Application No. 201921620824.3, filed on Sep. 26, 2019, the entirety of which are incorporated by reference herein.

### BACKGROUND OF THE INVENTION

### Field of the Invention

The application relates in general to a fingerprint sensing module, and in particular, to an under-display fingerprint image sensing module.

### Description of the Related Art

Biological identification technology has become increasingly mature, and different biological features can be used to identify individual users. Since the recognition rate and accuracy of fingerprint identification technology are better than those of other biological-feature identification technologies, fingerprint identification and verification are used extensively in various areas.

Fingerprint identification and verification technology detects a user's fingerprint pattern, captures fingerprint data from the fingerprint pattern, and saves the fingerprint data to the memory as a template, or directly saves the fingerprint pattern. Thereafter, the user presses or swipes a finger on or over the fingerprint sensor so that a fingerprint pattern is sensed and fingerprint data is captured, which can then be compared against the template or the stored fingerprint pattern. If the two match, then the user's identity is confirmed.

FIG. 1 is a schematic diagram of a conventional optical fingerprint sensing device, and FIG. 2 is an enlarged view of the portion A1 in FIG. 1. Referring to FIG. 1, the conventional optical fingerprint sensing device primarily comprises a display panel module D, a base plate B, a substrate P (e.g. circuit board), a frame H, a lens M1, an image sensor S, and an IR filter F. The substrate P is disposed on the base plate B, the frame H and the image sensor S are disposed on the substrate P, and the lens M1 is affixed in an opening of the frame H.

The display panel module D includes a display element D1 and a light permeable element D2 disposed on the display element D1. It should be noted that the display element D1 can emit light through the light permeable element D2 to the finger in a sensing area R of the display panel module D, and light is reflected by the finger and then bounces out of the display element D1, as indicated by the light L illustrated in FIG. 1. Subsequently, light can propagate through the lens M1 and the IR filter F to reach the image sensor S, whereby data storage and biological identification on the fingerprint pattern can be performed.

When a conventional optical fingerprint sensing device is used to capture a fingerprint pattern, infrared light generated by the light source may cause interference noise, thereby reducing the quality of the images captured by the image sensor S and the accuracy of fingerprint identification. Though the IR filter F (e.g. infrared cut-off filter sheet) can block infrared light from entering the image sensor S, miniaturization of the optical fingerprint sensing device could be difficult as the IR filter F usually has considerable thickness. Moreover, since the conventional IR filter F such as an optical sheet usually needs to be assembled on the upper side of the image sensor S by mechanical means, complexity of assembly and production cost of the optical fingerprint sensing device would increase.

### BRIEF SUMMARY OF INVENTION

In view of the aforementioned problems, an object of the invention is to provide an optical fingerprint sensing module for sensing a fingerprint pattern of a finger placed on a display panel module. The optical fingerprint sensing module includes a substrate, an image sensor disposed on the substrate, a frame disposed on the substrate, a lens affixed to the frame, and a plurality of micro-lenses, wherein the lens is located corresponding to a sensing area on the display panel module. The micro-lenses have an infrared cut-off material and are disposed above the image sensor, wherein light emitted from the display panel module is reflected by the finger and then sequentially propagates through the lens and the micro-lenses to the image sensor.

In some embodiments, no infrared filter is provided between the lens and the micro-lenses.

In some embodiments, the micro-lenses are formed on the micro-lenses by a coating, spraying or imprinting process.

In some embodiments, the micro-lenses has resin material.

In some embodiments, the display panel module is an OLED panel module or a TFT-LCD panel module.

Another object of the invention is to provide an optical fingerprint sensing module for sensing a fingerprint pattern of a finger placed on a display panel module. The optical fingerprint sensing module includes a substrate, an image sensor, disposed on the substrate, and a collimating layer disposed on the image sensor. The collimating layer has a plurality of collimating structures, wherein the collimating structures have an infrared cut-off material. Light emitted from the display panel module is reflected by the finger and then sequentially propagates through the collimating structures to the image sensor.

In some embodiments, no infrared filter is provided between the display panel module and the collimating layer.

In some embodiments, the collimating layer forms a plurality of through holes, and the collimating structures are disposed in the through holes.

In some embodiments, the collimating layer has a fiber optic plate (FOP), and the collimating structures have optical fiber material.

In some embodiments, the display panel module is an OLED panel module or a TFT-LCD panel module.

### BRIEF DESCRIPTION OF DRAWINGS

The invention can be more fully understood by reading the subsequent detailed description and examples with references made to the accompanying drawings, wherein:

FIG. 1 is a schematic diagram of a conventional optical fingerprint sensing device.

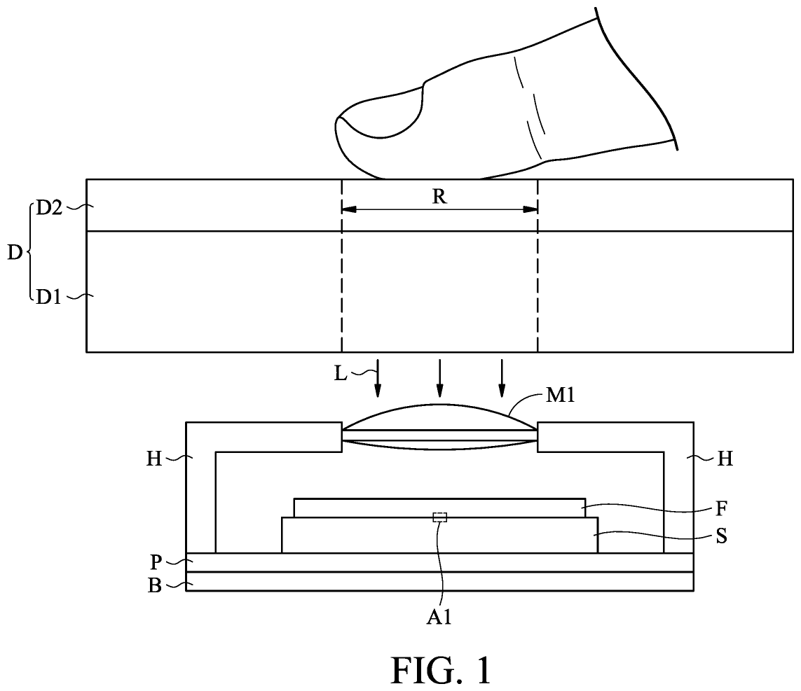

FIG. 2 is an enlarged view of the portion A1 in FIG. 1.

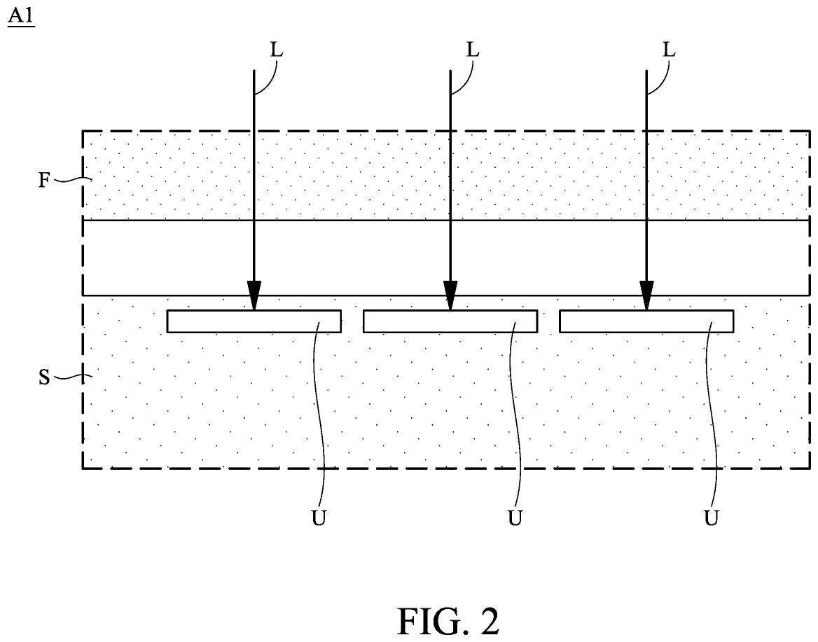

FIG. 3 is a schematic diagram of a micro-lens type optical fingerprint sensing device in accordance with an embodiment of the invention.

FIG. 4 is an enlarged view of the portion A2 in FIG. 3.

FIG. 5 is a schematic diagram of a collimator-type optical fingerprint sensing device in accordance with another embodiment of the invention.

### DETAILED DESCRIPTION OF INVENTION

The embodiments of an optical fingerprint sensing device are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Unless defined otherwise, all technical and scientific terms used herein have the same meaning as commonly understood by one of ordinary skill in the art to which this invention belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

In the following detailed description of the preferred embodiments, reference is made to the accompanying drawings, and in which specific embodiments of which the invention may be practiced are shown by way of illustration. In this regard, directional terminology, such as “top,” “bottom,” “left,” “right,” “front,” “back,” etc., is used with reference to the orientation of the figures being described. The components of the present invention can be positioned in a number of different orientations. As such, the directional terminology is used for the purposes of illustration and is in no way limiting.

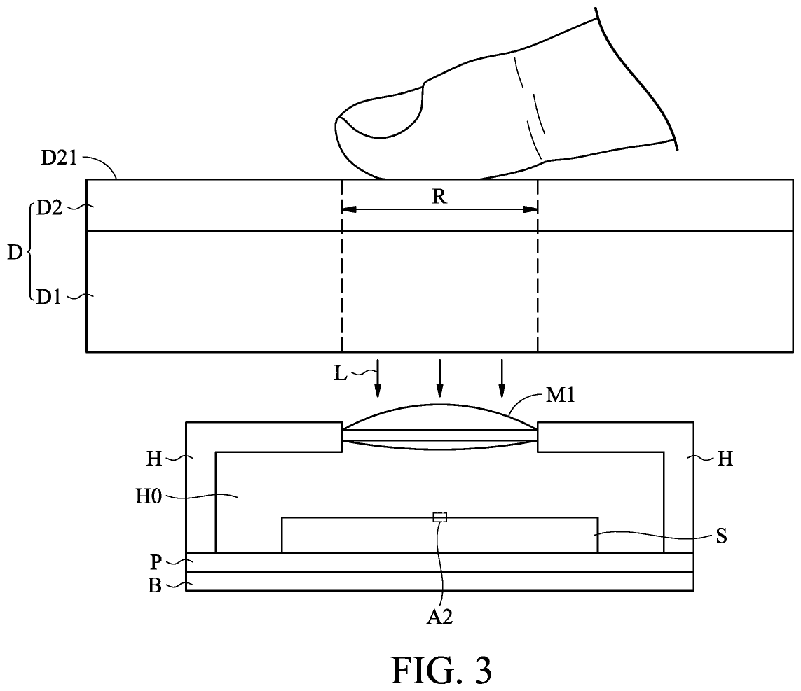

FIG. 3 is a schematic diagram of a micro-lens type optical fingerprint sensing device in accordance with an embodiment of the invention. As shown in FIG. 3, the optical fingerprint sensing device in this embodiment can be used to sense a fingerprint pattern of a finger. The optical fingerprint sensing device primarily includes a display panel module D and an optical fingerprint sensing module under the display panel module D. The optical fingerprint sensing module comprises a bottom plate B, a substrate P, a frame H, a lens M1, and an image sensor S. The substrate P is disposed on the bottom plate B, the frame H and the image sensor S are disposed on the substrate P, and the lens M1 is accommodated in an opening of the frame H.

For example, the image sensor S may comprise a Charge Coupled Device (CCD) or a CMOS Image Sensor (CIS), the substrate P may be a flexible printed circuit board, and the bottom plate B may comprise a plastic or metal material. Specifically, the hardness of the bottom plate B is greater than the hardness of the substrate P, so as to provide sufficient support for the substrate P and the image sensor S.

In this embodiment, the display panel module D comprises a display element D1 and a light permeable element D2 disposed on the display element D1. The light permeable element D2 may be a sheet glass, and the display element D1 may comprise Organic Light-Emitting Diodes (OLEDs), TFT-LCDs or touch display components. It should be noted that the display element D1 may include a plurality of light emitting units as light sources, thereby emitting light to pass through the light permeable element D2 to reach the finger thereon.

Still referring to FIG. 3, the frame H has a hollow structure and forms a receiving space HO for receiving the image sensor S. When using the optical fingerprint sensing device to capture a fingerprint pattern, the finger of a user can be placed within a sensing area R on a sensing surface D21 of the light permeable element D2. Subsequently, the light emitted from the light sources in the display element D1 can penetrate through the light permeable element D2 to reach the finger in the sensing area R, and the light is then reflected by the finger and bounces out of the display element D1, as indicated by the arrow L in FIG. 3. The light finally propagates through the lens M1 to reach the image sensor S.

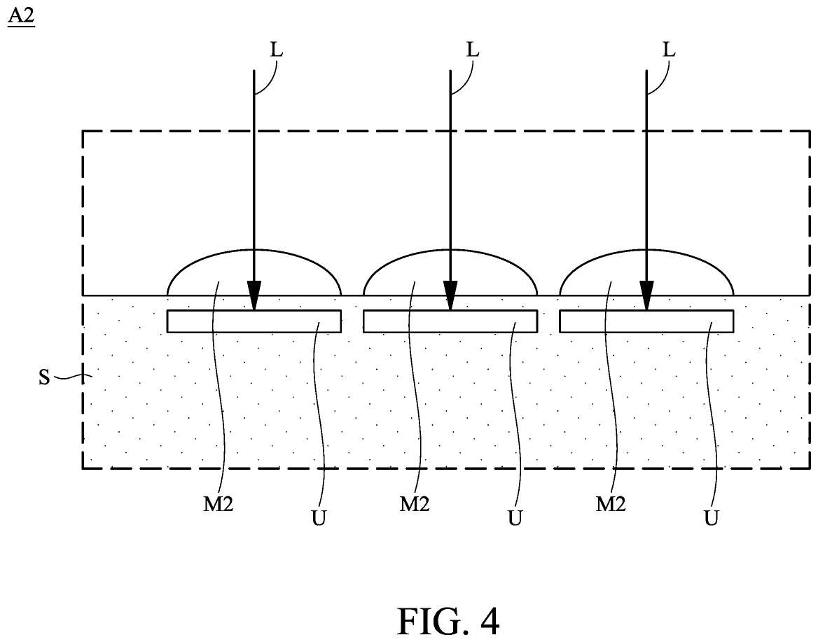

FIG. 4 is an enlarged view of the portion A2 in FIG. 3. As shown in FIG. 4, light L propagates through a plurality of micro-lenses M2 before entering the image sensor S. Specifically, a plurality of micro-lenses M2 are disposed on a surface of the image sensor S, and light L can penetrate through the micro-lenses M2 to reach the image sensing units U inside the image sensor S.

When the image sensor S receives the light that passes through the lens M1 and the micro-lenses M2, it can convert light signal into electrical signal, and the substrate P can transfer the electrical signal to a processor (not shown), wherein the electrical signal includes the fingerprint pattern information. Therefore, data storage and biological identification of the fingerprint pattern can be successfully performed.

It should be noted that the micro-lenses M2 comprise infrared cut-off material. Therefore, infrared light can be prevented from entering the image sensing units U inside image sensor S by the micro-lenses M2, and no IR filter sheet is needed to be disposed between the lens M1 and the micro-lenses M2, thus reducing production cost and facilitating miniaturization of the optical fingerprint sensing device. In some embodiment, the micro-lenses M2 may further comprise resin material, so that they can be firmly bonded to the surface of the image sensor S.

With the micro-lenses M2 formed on the image sensor S, the infrared light generated by the display element D1 can be efficiently prevented from entering the image sensor S, so that noise interference caused by the infrared light can be reduced, and the quality of the image generated by the image sensor S can be greatly improved. For example, the micro-lenses M2 may be formed on image sensor S by a coating, spraying, photolithography, etching, or imprinting process.

In this embodiment, the micro-lenses M2 may be connected to each other or separated from each other, and they are arranged on the surface of the image sensor S in a matrix, corresponding to the sensing units U inside image sensor S.

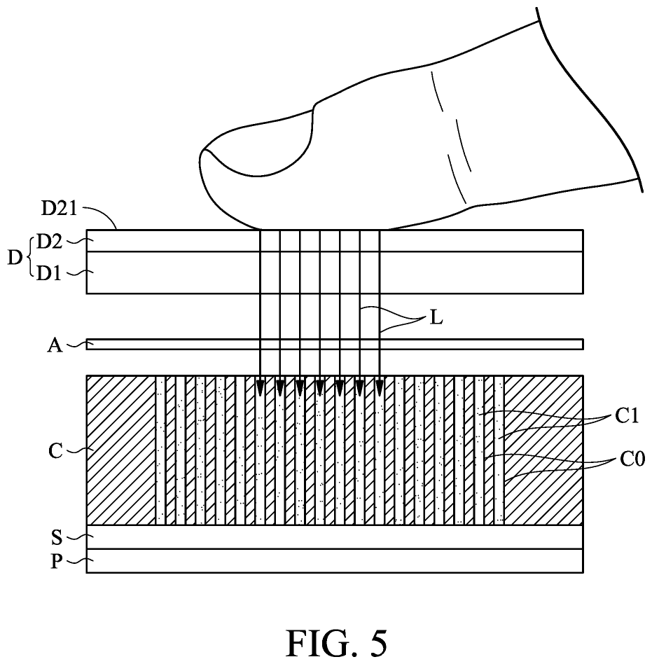

FIG. 5 is a schematic diagram of a collimator-type optical fingerprint sensing device in accordance with another embodiment of the invention. As shown in FIG. 5, the optical fingerprint sensing device in this embodiment can also be used to capture a fingerprint pattern, and it primarily includes a display panel module D and an optical fingerprint sensing module under the display panel module D. The optical fingerprint sensing module comprises a substrate P (e.g. flexible printed circuit board), an image sensor S, a collimating layer C, and at least an optical film A. The image sensor S is disposed on the substrate P, the collimating layer C is disposed on the image sensor S, and the optical film A is disposed between the display panel module D and the collimating layer C.

For example, the image sensor S may comprise a Charge Coupled Device (CCD) or a CMOS Image Sensor (CIS). In some embodiments, the image sensor S and the collimating layer C can be formed and stacked on the substrate P by semiconductor manufacturing processes. Referring to FIG. 5, a plurality of longitudinal through holes C0 are formed in the collimating layer C, and a plurality of collimating structures C1 are respectively formed in the through holes C0.

The display panel module D in FIG. 5 primarily includes a display element D1 and a light permeable element D2 disposed on the display element D1. The light permeable element D2 may be a sheet glass, and the display element D1 may comprise Organic Light-Emitting Diodes (OLEDs), TFT-LCDs or touch display components. It should be noted that the display element D1 may include a plurality of light emitting units as light sources, thereby emitting light through the light permeable element D2 to the finger thereon.

When using the collimator-type optical fingerprint sensing device of FIG. 5 to capture a fingerprint pattern, the finger of a user can be placed on a sensing surface D21 of the light permeable element D2. Subsequently, the light emitted from the light sources in the display element D1 can penetrate through the light permeable element D2 to reach the finger, and the light is then reflected by the finger and bounces out of the display element D1, as indicated by the arrow L in FIG. 5. The light finally propagates through the optical film A and the collimating layer C to reach the image sensor S. In this embodiment, the optical film A may comprise a polarizing film or a pinhole layer.

It should be noted that the light can be guided through the collimating structures C1 in the collimating layer C to reach the image sensor S, whereby serious cross-talk of light in the collimating layer C can be prevented. Specifically, the collimating structures C1 in this embodiment may comprise infrared cut-off material. Therefore, infrared light can be efficiently prevented from entering the image sensor S by the collimating structures C1 without providing other IR filter sheet, so as to reduce production cost and facilitate miniaturization of the optical fingerprint sensing device.

In some embodiments, the collimating layer C may be a fiber optic plate (FOP), and the collimating structures C1 may comprise optical fiber material such as glass and are doped with infrared cut-off material. Therefore, both the functions of light collimation and IR filtering can be performed by the collimating layer C.

It should be realized that and the optical fingerprint sensing devices in all the aforementioned embodiments are under-display type fingerprint image sensing devices provided with low light level imaging sensors, and the light sources thereof may have low illumination level (e.g. OLEDs). Hence, when even a small quantity of infrared light enters the image sensor S, it may cause considerable noise and reduce the quality of the image.

To address the above-mentioned problems, an embodiment of the invention provides a micro-lens type optical fingerprint sensing device that has a lens comprising infrared cut-off material, and another embodiment of the invention provides a collimator-type optical fingerprint sensing device that has a collimating layer comprising infrared cut-off material. Thus, no other IR filter sheet is needed to be in the optical fingerprint sensing device, and infrared light can be efficiently prevented from entering the image sensor, so as to greatly improve the quality of the images captured by the image sensor and the accuracy of fingerprint identification.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, compositions of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. Moreover, the scope of the appended claims should be accorded the broadest interpretation so as to encompass all such modifications and similar arrangements.

While the invention has been described by way of example and in terms of preferred embodiment, it should be understood that the invention is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. An optical fingerprint sensing module for sensing a fingerprint pattern of a finger on a display panel module, comprising:
a substrate;
an image sensor, disposed on the substrate;
a frame, disposed on the substrate;
a lens, affixed to the frame and disposed in a location that corresponds to a sensing area on the display panel module; and
a plurality of micro-lenses, comprising infrared cut-off material and disposed above the image sensor, wherein light emitted from the display panel module is reflected by the finger and then sequentially propagates through the lens and the micro-lenses to the image sensor.

2. The optical fingerprint sensing module as claimed in claim 1, wherein no infrared filter is provided between the lens and the micro-lenses.

3. The optical fingerprint sensing module as claimed in claim 1, wherein the micro-lenses are formed on the micro-lenses by a coating, spraying or imprinting process.

4. The optical fingerprint sensing module as claimed in claim 1, wherein the micro-lenses comprise resin material.

5. The optical fingerprint sensing module as claimed in claim 1, wherein the display panel module is an OLED panel module or a TFT-LCD panel module.

6. An optical fingerprint sensing module for sensing a fingerprint pattern of a finger on a display panel module, comprising:
a substrate;
an image sensor, disposed on the substrate; and
a collimating layer, disposed on the image sensor and comprising a plurality of collimating structures, wherein the collimating structures comprise infrared cut-off material, and light emitted from the display panel module is reflected by the finger and then sequentially propagates through the collimating structures to the image sensor.

7. The optical fingerprint sensing module as claimed in claim 6, wherein no infrared filter is provided between the display panel module and the collimating layer.

8. The optical fingerprint sensing module as claimed in claim 6, wherein the collimating layer forms a plurality of through holes, and the collimating structures are disposed in the through holes.

9. The optical fingerprint sensing module as claimed in claim 6, wherein the collimating layer comprises a fiber optic plate (FOP), and the collimating structures comprise optical fiber material.

10. The optical fingerprint sensing module as claimed in claim 6, wherein the display panel module is an OLED panel module or a TFT-LCD panel module.
